(19) United States
(12) Patent Application Publication
(10) Pub. No.: US 2026/0337785 A1
(43) Pub. Date: Oct. 29, 2026

(54) LAMINATE AND METHOD FOR MANUFACTURING LAMINATE

(71) Applicant: FUJIFILM Corporation, Tokyo (JP)

(72) Inventors: Yusuke FUJII, Kanagawa (JP); Kousuke Nakada, Kanagawa (JP)

(73) Assignee: FUJIFILM Corporation, Tokyo (JP)

(21) Appl. No.: 19/700,361

(22) Filed: Jun. 7, 2026

Related U.S. Application Data
(63) Continuation of application No. PCT/JP2025/000786, filed on Jan. 14, 2025.

(30) Foreign Application Priority Data
Jan. 18, 2024 (JP) 2024-006048

(51) Int. Cl. C23C 28/00

(52) U.S. Cl. CPC C23C 28/3455

(57) ABSTRACT

The present invention provides a laminate and a method for manufacturing a laminate, in which adhesiveness after plating liquid immersion is excellent. The laminate according to the present invention includes a substrate, a metal oxide layer containing a first metal atom selected from the group consisting of a titanium atom, a zirconium atom, and an aluminum atom, and a metal layer X that is disposed adjacent to the metal oxide layer and contains a second metal atom of a different kind from the first metal atom, in which a thickness of the metal oxide layer is 50 to 2,000 nm.

### CROSS-REFERENCE TO RELATED APPLICATIONS

This application is a Continuation of PCT International Application No. PCT/JP2025/000786 filed on Jan. 14, 2025, which claims priority under 35 U.S.C. § 119(a) to Japanese Patent Application No. 2024-006048 filed on Jan. 18, 2024. The above applications are hereby expressly incorporated by reference, in their entirety, into the present application.

### BACKGROUND OF THE INVENTION

### 1. Field of the Invention

The present invention relates to a laminate and a method for manufacturing a laminate.

### 2. Description of the Related Art

A method of forming a conductive layer by applying a conductive ink containing a metal component onto a substrate with an ink jet recording method has been widely known. As a laminate formed using a conductive ink used in such an ink jet recording method, WO2010/029934A discloses a substrate subjected to a surface treatment with a predetermined coupling agent.

### SUMMARY OF THE INVENTION

The present inventors have conducted studies on the laminate described in WO2010/029934A, and have found that, in a case where the laminate is immersed in a plating liquid, a metal layer is easily peeled off from the laminate.

Hereinafter, the fact that the metal layer is not easily peeled off from the laminate in a case where the laminate is immersed in a plating liquid is also referred to as “excellent adhesiveness after plating liquid immersion”.

Therefore, an object of the present invention is to provide a laminate having excellent adhesiveness after plating liquid immersion, and a method for manufacturing a laminate.

In order to achieve the above objects, the inventors of the present invention conducted intensive studies. As a result, the inventors have found that the objects can be achieved by the following constitutions.

[1]

A laminate including:
a substrate;
a metal oxide layer containing a first metal atom selected from the group consisting of a titanium atom, a zirconium atom, and an aluminum atom; and
a metal layer X disposed adjacent to the metal oxide layer and containing a second metal atom of a different kind from the first metal atom,
in which a thickness of the metal oxide layer is 50 to 2,000 nm.
   [2]

The laminate according to [1], in which the metal layer X contains a silicon atom.

[3]

The laminate according to [1] or [2], in which the metal layer X contains a silicon atom, and
the number of silicon atoms in the metal layer X is 0.1 to 10.0 at % with respect to a total number of atoms of the metal layer X.
   [4]

The laminate according to any one of [1] to [3], in which the metal layer X contains a silicon atom, an oxygen atom, and a carbon atom, and
a ratio of an atomic number of the silicon atom to a total atomic number of the oxygen atom and the carbon atom in the metal layer X is 0.25 or more.
   [5]

The laminate according to any one of [1] to [4], in which a thickness of the metal layer X is 0.1 to 3.0 μm.

[6]

The laminate according to any one of [1] to [5], further including:
a metal layer Y, on the metal layer X, the metal layer Y containing a third metal atom of a different kind from both the first metal atom and the second metal atom.
   [7]

A method for manufacturing a laminate, including:
a step 1 of applying a composition containing a coupling agent selected from the group consisting of a titanium coupling agent, a zirconium coupling agent, and an aluminum coupling agent onto a substrate to form a metal oxide layer containing a first metal atom selected from the group consisting of a titanium atom, a zirconium atom, and an aluminum atom; and
a step 2 of applying an ink containing a metal compound selected from the group consisting of a metal salt and a metal complex onto the metal oxide layer to form a metal layer X containing a second metal atom of a different kind from the first metal atom,
in which a thickness of the metal oxide layer is 50 to 2,000 nm.
   [8]

The method for manufacturing a laminate according to [7], in which the ink contains a silane coupling agent.

[9]

The method for manufacturing a laminate according to [7] or [8], further including: a step 3 of subjecting the metal layer X to a plating treatment to form, on the metal layer X, a metal layer Y containing a third metal atom of a different kind from both the first metal atom and the second metal atom, after the step 2.

According to the present invention, it is possible to provide a laminate having excellent adhesiveness after plating liquid immersion, and a method for manufacturing a laminate.

### DESCRIPTION OF THE PREFERRED EMBODIMENTS

Hereinafter, the present invention will be described in detail.

The description of configuration requirements described below may be made based on typical embodiments of the present invention, but the present invention is not limited to such embodiments.

In the present specification, the numerical range expressed by using “to” means a range including the numerical values before and after “to” as the lower limit value and the upper limit value. In a numerical range described in a stepwise manner in the present specification, an upper limit value or a lower limit value described in a certain numerical range may be replaced with an upper limit value or a lower limit value in another numerical range described in a stepwise manner. In addition, in the numerical range described in the present specification, an upper limit value or a lower limit value described in a certain numerical range may be replaced with values shown in Examples.

In the present specification, for each component, one kind of substance corresponding to each component may be used alone, or two or more kinds thereof may be used in combination. Here, in a case where two or more kinds of substances are used for each component, the content of the component indicates a total content of two or more substances unless otherwise specified.

In the present specification, a combination of two or more preferred aspects is a more preferred aspect.

In the present specification, the meaning of the term “step” includes not only an independent step but also a step whose intended purpose is achieved even in a case where the step is not clearly distinguished from other steps.

### [Laminate]

The laminate is a laminate including a substrate,
a metal oxide layer that includes a first metal atom selected from the group consisting of a titanium atom, a zirconium atom, and an aluminum atom, and
a metal layer X that is disposed adjacent to the metal oxide layer and that includes a second metal atom of a kind different from the first metal atom,
in which a thickness of the metal oxide layer is 50 to 2,000 nm.

The reason why the laminate has excellent adhesiveness after plating liquid immersion is not clear, but is presumed as follows.

For example, in a case where a laminate having a metal layer is subjected to a plating treatment to form a metal layer different from the metal layer, thereby thickening the metal layer, the metal layer may be peeled off from the laminate during the plating treatment. On the other hand, it is presumed that, in the laminate according to the embodiment of the present invention, since the laminate has the metal oxide layer containing the first metal atom, which is disposed adjacent to the metal layer X, and the thickness of the metal oxide layer is in a specific range, the metal layer X is less likely to be peeled off from the laminate.

Hereinafter, each member that can be included in the laminate will be described in detail.

### <Substrate>

The laminate includes a substrate.

Specifically, examples of the material of the substrate include synthetic resins such as polyimide, polyethylene terephthalate, polybutylene terephthalate, polytrimethylene terephthalate, polyethylene naphthalate, polybutylene naphthalate, polycarbonate, polyurethane, polyethylene, polypropylene, polyvinyl chloride, polystyrene, polyvinyl acetate, an acrylic resin, an acrylonitrile styrene resin (AS resin), an acrylonitrile-butadiene-styrene copolymer (ABS resin), triacetyl cellulose, polyamide, polyacetal, polyphenylene sulfide, polysulfone, an epoxy resin, a glass epoxy resin, a melamine resin, a phenol resin, a urea resin, an alkyd resin, a fluororesin, and polylactic acid; inorganic materials such as copper, steel, aluminum, silicon, soda glass, alkali-free glass, and indium tin oxide (ITO); and papers such as base paper, art paper, coated paper, cast coated paper, resin coated paper, and synthetic paper.

The substrate may be one layer or two or more layers. In a case where the substrate is composed of two or more layers, two or more substrates made of different materials may be laminated.

A form of the substrate is preferably sheet-like or film-like. A thickness of the substrate is preferably 20 to 2,000 μm.

The substrate may be subjected to a surface treatment.

Examples of the surface treatment include known methods such as an ozone treatment, a plasma treatment, a corona treatment, a primer treatment, and a roughening treatment.

### <Metal Oxide Layer>

The laminate includes a metal oxide layer.

A thickness of the metal oxide layer is 50 to 2,000 nm, preferably 60 to 1,000 nm and more preferably 100 to 500 nm.

The metal oxide layer includes a first metal atom selected from the group consisting of a titanium atom, a zirconium atom, and an aluminum atom.

From the viewpoint of more excellent adhesiveness after plating liquid immersion, the metal oxide layer preferably includes a titanium atom.

In addition, the metal oxide layer preferably includes an oxide of the first metal atom selected from the group consisting of titanium oxide, zirconium oxide, and aluminum oxide, and more preferably includes titanium oxide.

The metal oxide layer may include other metal atoms or may include two or more kinds of the first metal atoms or other atoms as long as the metal oxide layer includes the first metal atom.

In the metal oxide layer, the number of first metal atoms is preferably 80 to 100 at %, more preferably 90 to 100 at %, and still more preferably 99 to 100 at % with respect to the total number of metal atoms included in the metal oxide layer.

In addition, a content of the oxide of the first metal atom is preferably 80 to 100% by mass, more preferably 90 to 100% by mass, and still more preferably 99 to 100% by mass with respect to the total mass of the metal oxide layer.

The number of first metal atoms and the content of the oxide of the first metal atom can be measured using, for example, X-ray photoelectron spectroscopy (XPS) and an X-ray fluorescence analysis (XRF).

### <Metal Layer X>

The laminate includes a metal layer X.

The metal layer X is disposed adjacent to the metal oxide layer and includes a second metal atom of a kind different from the first metal atom.

The fact that the metal layer X is disposed adjacent to the metal oxide layer means that the metal layer X is disposed to be in contact with the metal oxide layer, and means that there is no other layer between the metal layer X and the metal oxide layer.

The second metal atom is of a kind different from the first metal atom. The second metal atom may be of a kind different from the first metal atom selected from the group consisting of a titanium atom, a zirconium atom, and an aluminum atom. For example, in a case where the first metal atom is a titanium atom, the second metal atom may be a metal atom other than the titanium atom, and may be a zirconium atom or an aluminum atom.

In addition, it is preferable that the second metal atom is of a kind different from any of the metal atoms contained in the metal oxide layer. For example, in a case where the metal oxide layer contains a titanium atom and a zirconium atom as the first metal atom and contains an indium atom and a tin atom as other metal atoms, it is preferable that the second metal atom is of a kind different from any of the titanium atom, the zirconium atom, the indium atom, and the tin atom.

Examples of the second metal atom include a silver atom, a copper atom, a gold atom, an aluminum atom, a magnesium atom, a tungsten atom, a molybdenum atom, a zinc atom, a nickel atom, a palladium atom, an iron atom, a platinum atom, a tin atom, and a lead atom. Among these, from the viewpoint of conductivity, the second metal atom preferably includes at least one selected from the group consisting of a silver atom, a gold atom, a platinum atom, a nickel atom, a palladium atom, and a copper atom, more preferably includes at least one of a silver atom or a copper atom, and still more preferably includes a silver atom.

The metal layer X preferably contains a silicon atom.

In a case where the metal layer X contains a silicon atom, the interaction with the metal oxide layer is stronger, and the adhesiveness after plating liquid immersion is more excellent. In the present specification, a metal atom does not include a metalloid atom such as a boron atom, a silicon atom, and a germanium atom.

The metal layer X preferably contains a second metal atom, a silicon atom, a carbon atom, and an oxygen atom. In a case where the metal layer X contains a silicon atom, a carbon atom, and an oxygen atom, it is preferable that the silicon atom, the carbon atom, and the oxygen atom are derived from a coupling agent used in the step 1 described later. In other words, the metal layer X preferably contains a second metal atom and a hydrolysate or a hydrolysis condensate of a coupling agent. The coupling agent is a coupling agent used in the step 1 described later, and is a coupling agent selected from the group consisting of a titanium coupling agent, a zirconium coupling agent, and an aluminum coupling agent.

The hydrolysate of the coupling agent is intended to be a compound obtained by hydrolyzing a hydrolyzable group in the coupling agent. The above-described hydrolysate may be a compound in which all of the hydrolyzable groups are hydrolyzed (completely hydrolyzed product) or a compound in which some of the hydrolyzable groups are hydrolyzed (partially hydrolyzed product). That is, the above-described hydrolysate may be the completely hydrolyzed product, the partially hydrolyzed product, or a mixture thereof.

In addition, the hydrolysis condensate of the coupling agent is intended to be a compound obtained by hydrolyzing a hydrolyzable group in the coupling agent and condensing the obtained hydrolysate. The above-described hydrolysis condensate may be a compound in which all of the hydrolyzable groups are hydrolyzed and all of the hydrolysates are condensed (completely hydrolyzed and condensed product) or a compound in which some of the hydrolyzable groups are hydrolyzed and some of the hydrolysates are condensed (partially hydrolyzed and condensed product). That is, the above-described hydrolysis condensate may be the completely hydrolyzed and condensed product, the partially hydrolyzed and condensed product, or a mixture thereof.

The number of second metal atoms is preferably 80 to 100 at % with respect to the total number of metal atoms contained in the metal layer X, more preferably 90 to 100 at %, and still more preferably 99 to 100 at %.

The number of second metal atoms is preferably 30 to 99 at % with respect to the total number of atoms of the metal layer X, more preferably 50 to 95 at %, and still more preferably 60 to 95 at %.

The number of second metal atoms can be measured by, for example, the above-described measuring method for the first metal atom.

The number of silicon atoms is preferably 0.1 to 20.0 at % with respect to the total number of atoms of the metal layer X, more preferably 0.1 to 10.0 at %, and still more preferably 0.1 to 7.0 at %.

The number of carbon atoms is preferably 0 to 30.0 at % with respect to the total number of atoms of the metal layer X, more preferably 0.1 to 20.0 at %, and still more preferably 0.1 to 10.0 at %.

The number of oxygen atoms is preferably 0 to 30.0 at % with respect to the total number of atoms of the metal layer X, more preferably 0.1 to 20.0 at %, and still more preferably 0.1 to 10.0 at %.

The number of silicon atoms, the number of carbon atoms, and the number of oxygen atoms can be measured by, for example, the above-described measuring method for the first metal atom.

In a case where the metal layer X contains a silicon atom, an oxygen atom, and a carbon atom, a ratio of the number of silicon atoms to the total number of oxygen atoms and carbon atoms (the number of silicon atoms/the total number of oxygen atoms and carbon atoms) in the metal layer X is preferably 0.10 or more, and from the viewpoint of excellent conductivity and excellent suppression of migration occurrence, the ratio is more preferably 0.25 or more. The upper limit thereof is preferably 0.90 or less and more preferably 0.70 or less.

The thickness of the metal layer X is preferably 0.1 to 5.0 μm, and from the viewpoint of more excellent adhesiveness after plating liquid immersion, the thickness is more preferably 0.1 to 3.0 μm.

### <Metal Layer Y>

The laminate may include a metal layer Y

The metal layer Y is disposed on the metal layer X and contains a third metal atom different in kind from both the first metal atom and the second metal atom. The metal layer Y is preferably a metal layer formed in a step 3 described later.

The third metal atom is different in kind from the first metal atom and the second metal atom. The third metal atom may be any kind as long as it is different from the first metal atom and the second metal atom. For example, in a case where the first metal atom is a titanium atom and the second metal atom is a silver atom, it is preferable that the third metal atom is a metal atom different in kind from both the titanium atom and the silver atom, that is, the third metal atom is a metal atom other than the titanium atom and the silver atom.

The third metal atom preferably includes at least one selected from the group consisting of a gold atom, a silver atom, a copper atom, a platinum atom, a palladium atom, a nickel atom, a cobalt atom, a tin atom, and an iron atom. Among these, from the viewpoint of conductivity, adhesiveness, and cost, the third metal atom is preferably a nickel atom, an iron atom, or a copper atom.

The metal layer Y may include other atoms as long as it includes the third metal atom.

Examples of the other atoms include atoms of various components that can be contained in the plating liquid described later.

The number of third metal atoms is preferably 80 to 100 at %, more preferably 90 to 100 at %, and still more preferably 99 to 100 at % with respect to the total number of atoms of the metal layer Y

The thickness of the metal layer Y is preferably 1 to 50 μm and more preferably 1 to 30 μm.

### [Method for Producing Laminate]

The method for manufacturing the laminate is not particularly limited as long as the above-described laminate can be manufactured.

In particular, the method for manufacturing the laminate preferably includes a step 1 of applying a composition including a coupling agent (hereinafter, also referred to as “specific coupling agent”) selected from the group consisting of a titanium coupling agent, a zirconium coupling agent, and an aluminum coupling agent onto a substrate to form a metal oxide layer including a first metal atom selected from the group consisting of a titanium atom, a zirconium atom, and an aluminum atom, and
a step 2 of applying an ink including a metal compound selected from the group consisting of a metal salt and a metal complex onto the metal oxide layer to form a metal layer X including a second metal atom of a different type from the first metal atom,
in which a thickness of the metal oxide layer is 50 to 2,000 nm.

In a case where the metal layer X is formed from an ink including a metal compound selected from the group consisting of a metal salt and a metal complex (particularly, an ink including the above-described metal compound and not including metal particles), the formed metal layer X has more excellent adhesiveness after plating liquid immersion.

The method for manufacturing the laminate also preferably further includes, after the step 2, a step 3 of subjecting the metal layer X to a plating treatment to form a metal layer Y including a third metal atom of a different type from both the first metal atom and the second metal atom on the metal layer X.

### <Step 1>

The step 1 is a step of applying a composition including a specific coupling agent onto a substrate to form a metal oxide layer including a first metal atom selected from the group consisting of a titanium atom, a zirconium atom, and an aluminum atom.

The metal oxide layer can be formed on the substrate by the step 1.

It is preferable that the first metal atom included in the metal oxide layer is a metal atom constituting the specific coupling agent included in the composition. In other words, it is preferable that the first metal atom and the metal atom constituting the specific coupling agent are at least partially or entirely the same in terms of the type of the metal atom.

### (Substrate)

The substrate is the same as the substrate included in the laminate, and a preferred aspect thereof is also the same.

### (Composition)

The composition includes a specific coupling agent.

By using the specific coupling agent, it is possible to suppress the peeling of the metal layer X from the laminate in the obtained laminate.

The specific coupling agent preferably includes a titanium coupling agent.

Examples of the titanium coupling agent include titanium tetraisopropoxide, titanium tetran-butoxide, titanium tetraoctoxide, titanium tetra-2-ethylhexoxide, titanium dioctyloxybis(octylene glycolate), tetramethyl titanate, titanium acetylacetonate, titanium diisopropoxybis(acetylacetonate), titanium tetraacetylacetonate, titanium diisopropoxybis(ethylacetoacetate), titanium ethylacetoacetate, titanium octanediolate, titanium diisopropoxybis(triethanolaminate), titanium triethanolaminate, ammonium titanium lactate, titanium lactate, polyhydroxytitanium stearate, and an oligomer thereof.

Among these, as the titanium coupling agent, a titanium coupling agent having tetravalent titanium is preferable, and a titanium coupling agent having an alkoxy ligand having 3 to 10 carbon atoms and tetravalent titanium is more preferable.

Examples of commercially available products of the titanium coupling agent include KR38S, KR44, KR46B, KR55, KR9SA, KRTTS, KR41B, KR138S, KR238S, and KR338X (manufactured by Ajinomoto Fine-Techno Co., Inc.), ATRON (NSi-500) manufactured by Nippon Soda Co., Ltd., and ORGATIX TC-130, ORGATIX PC-200, ORGATIX PC-250, ORGATIX PC-601, and ORGATIX PC-620 manufactured by Matsumoto Fine Chemical Co., Ltd.

Examples of the zirconium coupling agent include zirconium tetra-n-propoxide, zirconium tetra-n-butoxide, zirconium tributoxy monoacetylacetonate, zirconium monobutoxyacetylacetonate bis(ethylacetoacetate), zirconium dibutoxybis(ethylacetoacetate), zirconium tetraacetylacetonate, zirconium tributoxy monostearate, a zirconium chloride compound aminocarboxylic acid, zirconium monoacetylacetonate, zirconium bisacetylacetonate, zirconium monoethylacetoacetate, zirconium acetylacetonate bisethylacetoacetate, zirconium acetate, zirconium monostearate, and an oligomer thereof.

Among these, as the zirconium coupling agent, a zirconium coupling agent having tetravalent zirconium is preferable.

Examples of the aluminum coupling agent include aluminum isopropylate, mono sec-butoxyaluminum diisopropylate, aluminum sec-butyrate, aluminum ethylate, ethylacetoacetate aluminum diisopropylate, aluminum tris(ethylacetoacetate), alkylacetoacetate aluminum diisopropylate, aluminum monoacetylacetonate bis(ethylacetoacetate), aluminum tris(acetylacetoacetate), aluminum bisethylacetoacetate monoacetylacetonate, and an oligomer thereof.

The specific coupling agent may be used alone or in combination of two or more kinds thereof.

A content of the specific coupling agent is preferably 1% to 50% by mass and more preferably 2% to 40% by mass with respect to the total solid content of the composition.

In the present specification, the “solid content” of the composition means a component that forms a film formed of the composition. Typically, in a case where the composition contains a solvent (for example, an organic solvent, water, or the like), the “solid content” means all components excluding the solvent. In addition, in a case where the components are components which form the film, the components are considered to be solid contents even in a case where the components are liquid components.

The composition may contain a solvent.

Examples of the solvent include a hydrocarbon, a cyclic hydrocarbon, an aromatic hydrocarbon, a carbamate, an alkene, an amide, an ether, an ester, an alcohol, a thiol, a thioether, phosphine, and water.

The hydrocarbon is preferably a linear or branched hydrocarbon having 6 to 20 carbon atoms. Specific examples of the hydrocarbon include pentane, hexane, heptane, octane, nonane, decane, undecane, dodecane, tridecane, tetradecane, pentadecane, hexadecane, octadecane, nonadecane, and icosane.

The cyclic hydrocarbon is preferably a cyclic hydrocarbon having 6 to 20 carbon atoms. Specific examples of the cyclic hydrocarbon include cyclohexane, cycloheptane, cyclooctane, cyclononane, cyclodecane, and decalin.

Specific examples of the aromatic hydrocarbon include benzene, toluene, xylene, trimethylbenzene, and tetralin.

The ether may be any of a linear ether, a branched ether, or a cyclic ether. Specific examples of the ether include diethyl ether, dipropyl ether, dibutyl ether, methyl-t-butyl ether, tetrahydrofuran, tetrahydropyran, dihydropyran, and 1,4-dioxane.

The alcohol may be any of a primary alcohol, a secondary alcohol, or a tertiary alcohol.
Specific examples of the alcohol include ethanol, 1-propanol, 2-propanol, 1-methoxy-2-propanol, 1-butanol, 2-butanol, 1-pentanol, 2-pentanol, 3-pentanol, 1-hexanol, 2-hexanol, 3-hexanol, 1-octanol, 2-octanol, 3-octanol, tetrahydrofurfuryl alcohol, cyclopentanol, terpineol, decanol, isodecyl alcohol, lauryl alcohol, isolauryl alcohol, myristyl alcohol, isomyristyl alcohol, cetyl alcohol (cetanol), isocetyl alcohol, stearyl alcohol, isostearyl alcohol, oleyl alcohol, isooleyl alcohol, linoleyl alcohol, isolinoleyl alcohol, palmityl alcohol, isopalmityl alcohol, eicosyl alcohol, and isoeicosyl alcohol.

Specific examples of the ketone include acetone, methyl ethyl ketone, methyl isobutyl ketone, and cyclohexanone.

Specific examples of the ester include methyl acetate, ethyl acetate, isopropyl acetate, butyl acetate, isobutyl acetate, sec-butyl acetate, methoxybutyl acetate, ethylene glycol monomethyl ether acetate, ethylene glycol monoethyl ether acetate, ethylene glycol monobutyl ether acetate, diethylene glycol monomethyl ether acetate, diethylene glycol monoethyl ether acetate, diethylene glycol monobutyl ether acetate, propylene glycol monomethyl ether acetate, propylene glycol monoethyl ether acetate, propylene glycol monobutyl ether acetate, dipropylene glycol monomethyl ether acetate, dipropylene glycol monoethyl ether acetate, dipropylene glycol monobutyl ether acetate, and 3-methoxybutyl acetate.

### (Procedure)

Examples of a method for applying the composition include a printing method, a spray coating method, a roll coating method, a bar coating method, a curtain coating method, a spin coating method, and a die coating method (that is, a slit coating method).

The coating film formed by applying the composition may be dried as necessary.

Examples of the drying method include natural drying and heating drying. In addition, the drying may be performed at normal pressure or under reduced pressure.

The thickness of the metal oxide layer is 50 to 2,000 nm, preferably 60 to 1,000 nm, and more preferably 100 to 500 nm.

### <Step 2>

Step 2 is a step of applying an ink containing a metal compound selected from the group consisting of a metal salt and a metal complex onto the metal oxide layer to form a metal layer X containing a second metal atom of a different kind from the first metal atom.

The ink contains at least one of a metal complex or a metal salt.

From the viewpoint of excellent adhesiveness after plating liquid immersion, it is preferable that the ink does not contain metal particles.

Hereinafter, each of an ink containing a metal complex (hereinafter, also referred to as “metal complex ink”) and an ink containing a metal salt (hereinafter, also referred to as “metal salt ink”) will be described.

In addition, the ink preferably contains a second metal atom, and more preferably contains a metal compound containing a second metal atom. In other words, the ink is more preferably an ink containing a metal compound selected from the group consisting of a metal salt and a metal complex, the metal compound containing a second metal atom. The second metal atom is a metal atom of a different kind from the first metal atom contained in the metal oxide layer formed in Step 1. Examples of a preferred aspect of the second metal atom include the second metal atom contained in the above-described metal layer X.

### (Metal Complex Ink)

The metal complex ink is, for example, an ink obtained by dissolving a metal complex in a solvent.

### —Metal Complex—

Examples of the metal constituting the metal complex include silver, copper, gold, aluminum, magnesium, tungsten, molybdenum, zinc, nickel, palladium, iron, platinum, tin, and lead. Among these, from the viewpoint of conductivity, the metal constituting the metal complex preferably includes at least one selected from the group consisting of silver, gold, platinum, nickel, palladium, and copper, more preferably includes at least one of silver or copper, and still more preferably includes silver.

The metal complex can be obtained, for example, by reacting a metal salt with a complexing agent.

Examples of the method for manufacturing the metal complex include a method of adding a metal salt and a complexing agent to an organic solvent and stirring the mixture for a predetermined time. The stirring method is not particularly limited, and can be appropriately selected from known methods such as a stirring method using a stirrer, a stirring blade, or a mixer, and a method of applying ultrasonic waves.

Examples of the metal salt include an oxide, a thiocyanate, a sulfide, a chloride, a cyanide, a cyanate, a carbonate, an acetate, a nitrate, a nitrite, a sulfate, a phosphate, a perchlorate, a tetrafluoroborate, an acetylacetonate complex salt, and a carboxylate of a metal.

Examples of the complexing agent include an amine, an ammonium carbamate-based compound, an ammonium carbonate-based compound, an ammonium bicarbonate compound, and a carboxylic acid. Among these, from the viewpoint of conductivity and stability of the metal complex, the complexing agent preferably includes at least one selected from the group consisting of an ammonium carbamate-based compound, an ammonium carbonate-based compound, an amine, and a carboxylic acid having 8 to 20 carbon atoms.

The metal complex has a structure derived from a complexing agent, and is preferably a metal complex having a structure derived from at least one selected from the group consisting of an ammonium carbamate-based compound, an ammonium carbonate-based compound, an amine, and a carboxylic acid having 8 to 20 carbon atoms.

Examples of the amine as the complexing agent include ammonia, a primary amine, a secondary amine, a tertiary amine, and a polyamine.

Specific examples of a primary amine having a linear alkyl group include methylamine, ethylamine, 1-propylamine, n-butylamine, n-pentylamine, n-hexylamine, heptylamine, octylamine, nonylamine, n-decylamine, undecylamine, dodecylamine, tridecylamine, tetradecylamine, pentadecylamine, hexadecylamine, heptadecylamine, and octadecylamine.

Specific examples of a primary amine having a branched alkyl group include isopropylamine, sec-butylamine, tert-butylamine, isopentylamine, 2-ethylhexylamine, and tert-octylamine.

Specific examples of a primary amine having an alicyclic structure include cyclohexylamine and dicyclohexylamine.

Specific examples of a primary amine having a hydroxyalkyl group include ethanolamine, diethanolamine, triethanolamine, N-methylethanolamine, propanolamine, isopropanolamine, dipropanolamine, diisopropanolamine, tripropanolamine, and triisopropanolamine.

Specific examples of a primary amine having an aromatic ring include benzylamine, N,N-dimethylbenzylamine, phenylamine, diphenylamine, triphenylamine, aniline, N,N-dimethylaniline, N,N-dimethyl-p-toluidine, 4-aminopyridine, and 4-dimethylaminopyridine.

Specific examples of the secondary amine include dimethylamine, diethylamine, dipropylamine, dibutylamine, diphenylamine, dicyclopentylamine, and methylbutylamine.

Specific examples of the tertiary amine include trimethylamine, triethylamine, tripropylamine, and triphenylamine.

Specific examples of the polyamine include ethylenediamine, 1,3-diaminopropane, diethylenetriamine, triethylenetetramine, tetramethylenepentamine, hexamethylenediamine, tetraethylenepentamine, and a combination of these amines.

The amine is preferably an alkylamine, more preferably an alkylamine having 3 to 10 carbon atoms, and still more preferably a primary alkylamine having 4 to 10 carbon atoms.

In a case of reacting the metal salt with the amine, a ratio of a substance amount of the amine to a substance amount of the metal salt is preferably 1 to 15 times and more preferably 1.5 to 6 times. In a case in which the above ratio is within the above range, the complex formation reaction is completed, and a transparent solution is obtained.

Specific examples of the ammonium carbamate-based compound as the complexing agent include ammonium carbamate, methylammonium methylcarbamate, ethylammonium ethylcarbamate, 1-propylammonium 1-propylcarbamate, isopropylammonium isopropylcarbamate, butylammonium butylcarbamate, isobutylammonium isobutylcarbamate, amylammonium amylcarbamate, hexylammonium hexylcarbamate, heptylammonium heptylcarbamate, octylammonium octylcarbamate, 2-ethylhexylammonium 2-ethylhexylcarbamate, nonylammonium nonylcarbamate, and decylammonium decylcarbamate.

Specific examples of the ammonium carbonate-based compound as the complexing agent include ammonium carbonate, methylammonium carbonate, ethylammonium carbonate, 1-propylammonium carbonate, isopropylammonium carbonate, butylammonium carbonate, isobutylammonium carbonate, amylammonium carbonate, hexylammonium carbonate, heptylammonium carbonate, octylammonium carbonate, 2-ethylhexylammonium carbonate, nonylammonium carbonate, and decylammonium carbonate.

Specific examples of the ammonium bicarbonate-based compound as the complexing agent include ammonium bicarbonate, methylammonium bicarbonate, ethylammonium bicarbonate, 1-propylammonium bicarbonate, isopropylammonium bicarbonate, butylammonium bicarbonate, isobutylammonium bicarbonate, amylammonium bicarbonate, hexylammonium bicarbonate, heptylammonium bicarbonate, octylammonium bicarbonate, 2-ethylhexylammonium bicarbonate, nonylammonium bicarbonate, and decylammonium bicarbonate.

In a case where the metal salt is reacted with the ammonium carbamate-based compound, the ammonium carbonate-based compound, or the ammonium bicarbonate-based compound, a ratio of a substance amount of the ammonium carbamate-based compound, the ammonium carbonate-based compound, or the ammonium bicarbonate-based compound to a substance amount of the metal salt is preferably 0.01 to 1 times and more preferably 0.05 to 0.6 times.

Specific examples of the carboxylic acid as a complexing agent include caproic acid, caprylic acid, pelargonic acid, 2-ethylhexanoic acid, capric acid, neodecanoic acid, undecanoic acid, lauric acid, myristic acid, palmitic acid, stearic acid, palmitoleic acid, oleic acid, linoleic acid, and linolenic acid. Among these, the carboxylic acid is preferably a carboxylic acid having 8 to 20 carbon atoms and more preferably a carboxylic acid having 10 to 16 carbon atoms.

The content of the metal in the metal complex ink in terms of metal element is preferably 1% to 40% by mass, more preferably 5% to 30% by mass, and still more preferably 7% to 20% by mass with respect to the total mass of the metal complex ink.

The content of the metal complex in the metal complex ink is preferably 10% to 90% by mass, and more preferably 10% to 40% by mass with respect to the total mass of the metal complex ink. In a case where the content of the metal complex is 10% by mass or more, surface resistivity is further reduced. In a case where the content of the metal complex is 90% by mass or less, the jetting stability of the metal complex ink is further improved.

### —Silane Coupling Agent—

From the viewpoint of excellent adhesiveness after plating liquid immersion, the metal complex ink preferably contains a silane coupling agent.

The silane coupling agent is, for example, a compound having a hydrolyzable group directly bonded to a silicon atom.

Examples of the hydrolyzable group include an alkoxy group (preferably having 1 to 10 carbon atoms) and a halogen atom such as a chlorine atom, and from the viewpoint of stability, an alkoxy group is preferable.

The number of hydrolyzable groups directly bonded to an Si atom in the silane coupling agent is preferably 1 or more, more preferably 2 or more, and still more preferably 3 or more. The number thereof is not limited, and is, for example, 10,000 or less.

It is also preferable that the silane coupling agent has a reactive group.

Specific examples of the reactive group include an epoxy group, an oxetanyl group, a vinyl group, a (meth)acryl group, a styryl group, an amino group, an isocyanate group, a mercapto group, and an acid anhydride group.

The number of reactive groups in the silane coupling agent is preferably 1 or more, more preferably 2 or more, and still more preferably 3 or more. The number thereof is not limited, and is, for example, 10,000 or less.

The boiling point (standard boiling point) of the silane coupling agent is preferably 100 °C or higher, and more preferably 180 °C or higher.

Examples of the silane coupling agent include 3-glycidoxypropyltrimethoxysilane, 3-glycidoxypropyltriethoxysilane, vinyltrichlorosilane, vinyltrimethoxysilane, vinyltriethoxysilane, 2-(3,4-epoxycyclohexyl)ethyltrimethoxysilane, 3-glycidoxypropylmethyldiethoxysilane, p-styryltrimethoxysilane, 3-methacryloxypropylmethyldimethoxysilane, 3-methacryloxypropyltrimethoxysilane, 3-methacryloxypropylmethyldiethoxysilane, 3-methacryloxypropyltriethoxysilane, 3-acryloxypropyltrimethoxysilane, N-2-(aminoethyl)-3-aminopropylmethyldimethoxysilane, N-2(aminoethyl)3-aminopropyltrimethoxysilane, N-2(aminoethyl)3-aminopropyltriethoxysilane, 3-aminopropyltrimethoxysilane, 3-aminopropyltriethoxysilane, hexamethyldisilazane, 3-(2-aminoethylaminopropyl)dimethoxymethylsilane, 3-(2-aminoethylaminopropyl)trimethoxysilane, 2-(2-aminoethylthioethyl)diethoxymethylsilane, 2-(2-aminoethylthioethyl)triethoxysilane, 3-[2-(2-aminoethylaminoethylamino)propyl]trimethoxysilane, 3-triethoxysilyl-N-(1,3-dimethyl-butylidene)propylamine, N-phenyl-3-aminopropyltrimethoxysilane, N-(vinylbenzyl)-2-aminoethyl-3-aminopropyltrimethoxysilane hydrochloride, 3-ureidopropyltriethoxysilane, 3-chloropropyltrimethoxysilane, 3-isocyanatepropyltriethoxysilane, 3-mercaptopropylmethyldimethoxysilane, 3-mercaptopropyltrimethoxysilane, bis(triethoxysilylpropyl)tetrasulfide, imidazolylalkyltrialkoxysilane, diphenyldimethoxysilane, hexyltrimethoxysilane, decyltrimethoxysilane, trifluoropropyltrimethoxysilane, tetramethoxysilane, tetraethoxysilane, methyltrimethoxysilane, methyltriethoxysilane, dimethyltriethoxysilane, phenyltriethoxysilane, isocyanuric acid tris[3-(trimethoxysilyl)propyl], and 3-trimethoxysilylpropyl succinic acid anhydride.

The content of the silane coupling agent in the metal complex ink is preferably 0.1% to 5.0% by mass, more preferably 0.2% to 4.0% by mass, and still more preferably 0.5% to 3.0% by mass from the viewpoint that the conductivity and the suppression of migration occurrence are more excellent, with respect to the total mass of the metal complex ink.

### —Solvent—

The metal complex ink preferably includes a solvent.

The solvent is not particularly limited as long as it can dissolve the component contained in the metal complex ink, such as the metal complex.

From the viewpoint of ease of production, the boiling point of the solvent is preferably 30 °C to 300 °C, more preferably 50 °C to 200 °C, and still more preferably 80 °C to 180 °C.

It is preferable that the solvent is included in the metal complex ink such that the concentration of metal ions with respect to the metal complex (an amount of metals present as liberated ions with respect to 1 g of the metal complex) is 0.01 to 3.6 mmol/g; and it is more preferable that the solvent is included in the metal complex ink such that the concentration of the metal ions with respect to the metal complex is 0.05 to 2 mmol/g. In a case where the concentration of the metal ions is within the above-described range, the metal complex ink has excellent fluidity and exhibits excellent conductivity.

Examples of the solvent include water, hydrocarbons, cyclic hydrocarbons, aromatic hydrocarbons, terpenes, carbamates, alkenes, amides, ethers, esters, alcohols, thiols, thioethers, phosphines, and water.

The hydrocarbon is preferably a linear or branched hydrocarbon having 6 to 20 carbon atoms. Specific examples of the hydrocarbon include pentane, hexane, heptane, octane, nonane, decane, undecane, dodecane, tridecane, tetradecane, pentadecane, hexadecane, octadecane, nonadecane, and icosane.

The cyclic hydrocarbon is preferably a cyclic hydrocarbon having 6 to 20 carbon atoms.

Specific examples of the cyclic hydrocarbon include cyclohexane, cycloheptane, cyclooctane, cyclononane, cyclodecane, and decalin.

Specific examples of the aromatic hydrocarbon include benzene, toluene, xylene, trimethylbenzene, and tetralin.

Specific examples of the terpenes include α-bisabolol, borneol, camphene, camphor, δ-3-carene, β-caryophyllene, caryophyllene oxide, α-sedrene, β-eudesmol, fenchol, geraniol, guaiol, α-humulene, isoborneol, limonene, linalool, menthol, myrcene, nerol, cis-ocimene, trans-ocimene, α-phellandrene, α-pinene, β-pinene, sabinene, α-terpinene, α-terpineol, terpinolene, α-guaiene, elemene, farnesene, germacrene B, guia-1(10),11-diene, trans-2-pinanol, selina-3,7(11)-diene, and eudesm-7(11)-en-4-ol.

The ether may be any of a linear ether, a branched ether, or a cyclic ether. Specific examples of the ether include diethyl ether, dipropyl ether, dibutyl ether, methyl-t-butyl ether, tetrahydrofuran, tetrahydropyran, dihydropyran, and 1,4-dioxane.

The alcohol may be any of a primary alcohol, a secondary alcohol, or a tertiary alcohol.

Specific examples of the alcohol include ethanol, 1-propanol, 2-propanol, 1-methoxy-2-propanol, 1-butanol, 2-butanol, 1-pentanol, 2-pentanol, 3-pentanol, 1-hexanol, 2-hexanol, 3-hexanol, 1-octanol, 2-octanol, 3-octanol, tetrahydrofurfuryl alcohol, cyclopentanol, terpineol, decanol, isodecyl alcohol, lauryl alcohol, isolauryl alcohol, myristyl alcohol, isomyristyl alcohol, cetyl alcohol (cetanol), isocetyl alcohol, stearyl alcohol, isostearyl alcohol, oleyl alcohol, isooleyl alcohol, linoleyl alcohol, isolinoleyl alcohol, palmityl alcohol, isopalmityl alcohol, eicosyl alcohol, and isoeicosyl alcohol.

Specific examples of the ketone include acetone, methyl ethyl ketone, methyl isobutyl ketone, and cyclohexanone.

Specific examples of the ester include methyl acetate, ethyl acetate, isopropyl acetate, butyl acetate, isobutyl acetate, sec-butyl acetate, methoxybutyl acetate, ethylene glycol monomethyl ether acetate, ethylene glycol monoethyl ether acetate, ethylene glycol monobutyl ether acetate, diethylene glycol monomethyl ether acetate, diethylene glycol monoethyl ether acetate, diethylene glycol monobutyl ether acetate, propylene glycol monomethyl ether acetate, propylene glycol monoethyl ether acetate, propylene glycol monobutyl ether acetate, dipropylene glycol monomethyl ether acetate, dipropylene glycol monoethyl ether acetate, dipropylene glycol monobutyl ether acetate, and 3-methoxybutyl acetate.

### —Reducing Agent—

The metal complex ink may contain a reducing agent.

In a case where the metal complex ink contains a reducing agent, reduction of the metal complex into a metal is facilitated.

Specific examples of the reducing agent include a borohydride metal salt, an aluminum hydride salt, an amine, an alcohol, an organic acid, reducing sugar, a sugar alcohol, sodium sulfite, a hydrazine compound, dextrin, hydroquinone, hydroxylamine, ethylene glycol, glutathione, and an oxime compound.

The reducing agent may be the oxime compound disclosed in JP2014-516463A.

Specific examples of the oxime compound include acetone oxime, cyclohexanone oxime, 2-butanone oxime, 2,3-butanedione monoxime, dimethyl glyoxime, methyl acetoacetate monoxime, methyl pyruvate monoxime, benzaldehyde oxime, 1-indanone oxime, 2-adamantanone oxime, 2-methylbenzamide oxime, 3-methylbenzamide oxime, 4-methylbenzamide oxime, 3-aminobenzamide oxime, 4-aminobenzamide oxime, acetophenone oxime, benzamide oxime, and pinacolone oxime.

The content of the reducing agent in the metal complex ink is preferably 0.1% to 20% by mass, more preferably 0.3% to 10% by mass, and still more preferably 1% to 5% by mass with respect to the total mass of the metal complex ink.

### —Resin—

The metal complex ink may contain a resin.

In a case where the metal complex ink contains a resin, the adhesiveness of the metal complex ink to the substrate is improved.

Examples of the resin include polyester, polyethylene, polypropylene, polyacetal, polyolefin, polycarbonate, polyamide, a fluororesin, a silicone resin, ethyl cellulose, hydroxyethyl cellulose, rosin, an acrylic resin, polyvinyl chloride, polysulfone, polyvinylpyrrolidone, polyvinyl alcohol, a polyvinyl-based resin, polyacrylonitrile, polysulfide, polyamideimide, polyether, polyarylate, polyether ether ketone, polyurethane, an epoxy resin, a vinyl ester resin, a phenol resin, a melamine resin, and a urea resin.

### —Additives—

The metal complex ink may contain an additive such as an inorganic salt, an organic salt, an inorganic oxide such as silica, a surface conditioner, a wetting agent, a crosslinking agent, an antioxidant, a rust inhibitor, a heat stabilizer, a surfactant, a plasticizer, a curing agent, and a thickener.

The total content of the additives in the metal complex ink is preferably 20% by mass or less with respect to the total mass of the metal complex ink. The lower limit thereof may be 0% by mass or more.

### —Physical Properties—

A viscosity of the metal complex ink is preferably 1 to 100 mPa·s, more preferably 2 to 50 mPa·s, and still more preferably 3 to 30 mPa·s.

The viscosity of the metal complex ink is a value measured at 25 °C using a viscometer.

The viscosity is measured, for example, using a VISCOMETER TV-22 type viscometer (manufactured by TOKI SANGYO CO., LTD.).

A surface tension of the metal complex ink is not particularly limited, and is preferably 20 to 45 mN/m and more preferably 25 to 35 mN/m.

The surface tension is a value measured at 25 °C using a surface tensiometer. The surface tension is measured, for example, using DY-700 (manufactured by Kyowa Interface Science Co., Ltd.).

### (Metal Salt Ink)

The metal salt ink is, for example, a conductive ink obtained by dissolving a metal salt in a solvent.

### —Metal Salt—

The metal constituting the metal salt is the same as the metal constituting the above-described metal complex, and a preferred aspect thereof is also the same.

Examples of the metal salt include a metal benzoate, a metal halide, a metal carbonate, a metal citrate, a metal iodate, a metal nitrite, a metal nitrate, a metal acetate, a metal phosphate, a metal sulfate, a metal sulfide, a metal trifluoroacetate, and a metal carboxylate. It should be noted that two or more salts may be combined.

From the viewpoint of conductivity and storage stability, a metal carboxylate is preferable as the metal salt.

A carboxylic acid forming the metal carboxylate is preferably at least one selected from the group consisting of formic acid and a carboxylic acid having 1 to 30 carbon atoms, more preferably a carboxylic acid having 8 to 20 carbon atoms, and still more preferably a fatty acid having 8 to 20 carbon atoms. The fatty acid may be linear or branched, or may have a substituent.

Specific examples of the linear fatty acid include acetic acid, propionic acid, butyric acid, valeric acid, pentanoic acid, hexanoic acid, heptanoic acid, behenic acid, oleic acid, octanoic acid, nonanoic acid, decanoic acid, caproic acid, enanthic acid, caprylic acid, pelargonic acid, capric acid, and undecanoic acid.

Specific examples of the branched fatty acid include isobutyric acid, isovaleric acid, ethylhexanoic acid, neodecanoic acid, pivalic acid, 2-methylpentanoic acid, 3-methylpentanoic acid, 4-methylpentanoic acid, 2,2-dimethylbutanoic acid, 2,3-dimethylbutanoic acid, 3,3-dimethylbutanoic acid, and 2-ethylbutanoic acid.

Specific examples of a carboxylic acid having a substituent include hexafluoroacetylacetonic acid, hydroangelic acid, 3-hydroxybutyric acid, 2-methyl-3-hydroxybutyric acid, 3-methoxybutyric acid, acetonedicarboxylic acid, 3-hydroxyglutaric acid, 2-methyl-3-hydroxyglutaric acid, and 2,2,4,4-hydroxyglutaric acid.

The metal salt may be a commercially available product or may be produced by a known method.

A silver salt is produced, for example, by the following method.

First, a silver compound (for example, silver acetate) functioning as a silver supply source and formic acid or a fatty acid having 1 to 30 carbon atoms in the same quantity as the molar equivalent of the silver compound are added to an organic solvent such as ethanol. The mixture is stirred for a predetermined time by using an ultrasonic stirrer, and the formed precipitate is washed with ethanol and decanted. All of these steps can be performed at room temperature (25 °C). A mixing ratio of the silver compound to the formic acid or fatty acid having 1 to 30 carbon atoms in terms of the molar ratio is preferably 1:2 to 2:1, and more preferably 1:1.

The content of the metal in the metal salt ink in terms of metal element is preferably 1% to 40% by mass, more preferably 5% to 30% by mass, and still more preferably 7% to 20% by mass with respect to the total mass of the metal salt ink.

A content of the metal salt in the metal salt ink is preferably 10% to 90% by mass and more preferably 10% to 60% by mass with respect to the total mass of the metal salt ink. In a case where the content of the metal salt is 10% by mass or more, surface resistivity is further reduced. In a case where the content of the metal salt is 90% by mass or less, the jetting stability is further improved when the metal salt ink is jetted from the nozzle.

### —Solvent—

The metal salt ink may contain a solvent.

Examples of the solvent include a hydrocarbon, a cyclic hydrocarbon, an aromatic hydrocarbon, terpenes, a carbamate, an alkene, an amide, an ether, an ester, an alcohol, a thiol, a thioether, phosphine, and water.

The hydrocarbon is preferably a linear or branched hydrocarbon having 6 to 20 carbon atoms. Specific examples of the hydrocarbon include pentane, hexane, heptane, octane, nonane, decane, undecane, dodecane, tridecane, tetradecane, pentadecane, hexadecane, octadecane, nonadecane, and icosane.

The cyclic hydrocarbon is preferably a cyclic hydrocarbon having 6 to 20 carbon atoms.

Specific examples of the cyclic hydrocarbon include cyclohexane, cycloheptane, cyclooctane, cyclononane, cyclodecane, and decalin.

Specific examples of the aromatic hydrocarbon include benzene, toluene, xylene, trimethylbenzene, and tetralin.

Specific examples of the terpenes include α-bisabolol, borneol, camphene, camphor, δ-3-carene, β-caryophyllene, caryophyllene oxide, α-sedrene, β-eudesmol, fenchol, geraniol, guaiol, α-humulene, isoborneol, limonene, linalool, menthol, myrcene, nerol, cis-ocimene, trans-ocimene, α-phellandrene, α-pinene, β-pinene, sabinene, α-terpinene, α-terpineol, terpinolene, α-guaiene, elemene, farnesene, germacrene B, guia-1(10),11-diene, trans-2-pinanol, selina-3,7(11)-diene, and eudesm-7(11)-en-4-ol.

The ether may be any of a linear ether, a branched ether, or a cyclic ether. Specific examples of the ether include diethyl ether, dipropyl ether, dibutyl ether, methyl-t-butyl ether, tetrahydrofuran, tetrahydropyran, dihydropyran, and 1,4-dioxane.

The alcohol may be any of a primary alcohol, a secondary alcohol, or a tertiary alcohol.

Specific examples of the alcohol include ethanol, 1-propanol, 2-propanol, 1-methoxy-2-propanol, 1-butanol, 2-butanol, 1-pentanol, 2-pentanol, 3-pentanol, 1-hexanol, 2-hexanol, 3-hexanol, 1-octanol, 2-octanol, 3-octanol, tetrahydrofurfuryl alcohol, cyclopentanol, terpineol, decanol, isodecyl alcohol, lauryl alcohol, isolauryl alcohol, myristyl alcohol, isomyristyl alcohol, cetyl alcohol (cetanol), isocetyl alcohol, stearyl alcohol, isostearyl alcohol, oleyl alcohol, isooleyl alcohol, linoleyl alcohol, isolinoleyl alcohol, palmityl alcohol, isopalmityl alcohol, eicosyl alcohol, and isoeicosyl alcohol.

Specific examples of the ketone include acetone, methyl ethyl ketone, methyl isobutyl ketone, and cyclohexanone.

Specific examples of the ester include methyl acetate, ethyl acetate, isopropyl acetate, butyl acetate, isobutyl acetate, sec-butyl acetate, methoxybutyl acetate, ethylene glycol monomethyl ether acetate, ethylene glycol monoethyl ether acetate, ethylene glycol monobutyl ether acetate, diethylene glycol monomethyl ether acetate, diethylene glycol monoethyl ether acetate, diethylene glycol monobutyl ether acetate, propylene glycol monomethyl ether acetate, propylene glycol monoethyl ether acetate, propylene glycol monobutyl ether acetate, dipropylene glycol monomethyl ether acetate, dipropylene glycol monoethyl ether acetate, dipropylene glycol monobutyl ether acetate, and 3-methoxybutyl acetate.

### —Silane Coupling Agent—

The metal salt ink preferably contains a silane coupling agent.

The silane coupling agent is the same as the silane coupling agent in the above-described metal complex ink, and a preferred aspect thereof is also the same.

### —Other Components—

The metal salt ink may contain a reducing agent, a resin, and an additive.

The reducing agent, the resin, and the additive are the same as the various components in the above-described metal complex ink, and preferred aspects thereof are also the same.

### —Physical Properties—

The viscosity and the surface tension of the metal salt ink are the same as the viscosity and the surface tension of the above-described metal complex ink, respectively, and preferred aspects thereof are also the same.

Examples of the method of applying the ink include the method of applying the above-described composition.

The coating film formed by applying the ink may be dried as necessary. Examples of the drying method include natural drying and heating drying. In addition, the drying may be performed at normal pressure or under reduced pressure.

The method of applying the ink may be an ink jet recording method.

The ink jet recording method may be any of an electric charge control method of ejecting ink by using an electrostatic attraction force; a drop-on-demand method (pressure pulse method) of using a vibration pressure of a piezoelectric element; an acoustic ink jet method of converting an electric signal into an acoustic beam, irradiating ink, and ejecting the ink using a radiation pressure; or a thermal ink jet (Bubble jet (registered trademark)) method of heating ink to form air bubbles and utilizing the generated pressure.

As the ink jet recording method, the method described in JP1979-059936A (JP-S54-059936A) is preferable, and an ink jet recording method in which an ink subjected to an action of thermal energy undergoes a rapid change in volume and the ink is jetted from a nozzle by an action force caused by this change in state is more preferable.

In addition, examples of the ink jet recording method include the methods described in paragraphs 0093 to 0105 of JP2003-306623A.

Examples of an ink jet head used in the ink jet recording method include an ink jet head for a shuttle method of using short serial heads that are caused to scan a substrate in a width direction of the substrate to perform recording, and an ink jet head for a line method of using line heads that each consist of recording elements arranged for the entire area of at least one side of a substrate.

In the line method, since pattern formation can be performed on the entire surface of a substrate by scanning the substrate in a direction perpendicular to a direction in which the recording elements are arranged, a transport system such as a carriage that scans a short head is unnecessary.

In addition, since the movement of the carriage and complex scanning control between the carriage and the substrate are unnecessary and only the substrate moves, it is possible to increase the formation speed, as compared to the shuttle method.

Examples of the ink jet recording device for applying the insulating ink using the ink jet recording method include DMP-2850 (manufactured by Fujifilm Dimatix, Inc.).

The liquid droplet volume of the ink jetted from the nozzle of the ink jet head is preferably 1 to 100 pL (picoliters), more preferably 2 to 80 pL, and still more preferably 2 to 20 pL per dot.

The temperature of the substrate in a case of applying the ink is preferably 20 °C to 120 °C and more preferably 40 °C to 100 °C. In a case where the temperature of the substrate is 20 °C to 100 °C, the drying of the ink can be promoted while suppressing the deformation of the substrate due to heat.

### (Curing Treatment)

The method for manufacturing a laminate may further include a curing treatment of curing the applied ink by performing at least one of heating or light irradiation on the ink (coating film) applied onto the metal oxide layer. As a result, the ink is cured to form the metal layer X on the metal oxide layer.

Only one of the heating or the light irradiation may be performed, or both may be performed.

A temperature in a case of performing the heating (calcining temperature) is preferably 80 °C or higher, and more preferably 100 °C or higher. From the viewpoint of reducing damage to the substrate or the like, the calcining temperature is preferably 250 °C or lower and more preferably 200 °C or lower.

A time in a case of performing the heating (calcining time) is preferably 1 minute or longer. From the viewpoint of reducing damage to the substrate or the like, the calcining time is preferably 120 minutes or less and more preferably 60 minutes or less.

The substrate may be pre-heated before the ink is applied onto the substrate. In the present invention, such heating is also regarded as one form of the above-described heating. A temperature of the substrate in a case of applying the conductive ink onto the substrate is preferably 20 °C to 180 °C and more preferably 40 °C to 150 °C.

Specific examples of light in the light irradiation include ultraviolet rays and infrared rays.

A peak wavelength of the ultraviolet rays is preferably 200 to 405 nm, more preferably 250 to 400 nm, and still more preferably 260 to 400 nm.

An exposure amount in the light irradiation is preferably 0.1 to 10,000 J/cm² and more preferably 1 to 500 J/cm².

In the present invention, the time from the point in time at which the ink has landed on the substrate to the start of the heating or the light irradiation is preferably within 1 second, more preferably within 0.8 seconds, and still more preferably within 0.6 seconds. As a result, the reduction from the metal complex and the metal salt contained in the ink landed on the substrate to the metal is promoted (that is, the inhibition of the reduction by oxygen in the air can be suppressed), and thus a metal layer X having more excellent conductivity can be formed.

The step 2 may be repeated. As a result, the thickness of the metal layer X can be adjusted.

The thickness of the metal layer X is preferably 0.1 to 5.0 m and more preferably 0.1 to 3.0 μm.

The thickness of the metal layer X can be measured by acquiring a cross-sectional image of the metal layer X using a scanning electron microscope, measuring the lengths at 10 different positions of the portion corresponding to the thickness of the metal layer X, and calculating the arithmetic mean value of the lengths at the 10 points.

From the viewpoint that the conductivity of the metal layer X is more excellent, the volume resistivity of the metal layer X is preferably 6 μΩ·cm or less, more preferably 5 μΩ·cm or less, and still more preferably 4 μΩ·cm or less. The lower limit thereof is preferably 2 μΩ·cm or more.

From the viewpoint that the conductivity of the metal layer X is more excellent, the void ratio of the metal layer X is preferably 24% or less, more preferably 23% or less, and still more preferably 22% or less.

The lower limit value of the void ratio is not particularly limited, and is, for example, 0%.

### <Step 3>

The step 3 is a step of performing a plating treatment on the metal layer X to form a metal layer Y containing a third metal atom different from both the first metal atom and the second metal atom on the metal layer X, after the step 2.

The metal layer Y is the same as the metal layer Y which can be included in the above-described laminate, and a preferred aspect thereof is also the same.

Examples of the plating treatment method include an electroless plating treatment method and an electrolytic plating treatment method, and a known plating treatment method may be used.

In the electroless plating method, for example, by bringing an electroless plating liquid into contact with at least a part or the entire surface of the substrate, the metal oxide layer, and the metal layer X, a metal such as copper contained in the electroless plating liquid can be precipitated to form an electroless plating layer (coating) consisting of a metal coating.

The electroless plating liquid is preferably a liquid containing the third metal atom contained in the above-described metal layer Y, a reducing agent, and a solvent.

Examples of the reducing agent include hypophosphorous acid, sodium hypophosphite, dimethylamine borane, hydrazine, formaldehyde, sodium borohydride, and phenol.

Examples of the solvent include a solvent which can be included in the above-described composition.

The electroless plating liquid may contain a complexing agent.

Examples of the complexing agent include organic acids and salts thereof (for example, a sodium salt, a potassium salt, and an ammonium salt), and amine compounds such as ethylenediamine, diethylenetriamine, and triethylenetetramine.

Examples of the organic acid and the salts thereof include monocarboxylic acids such as acetic acid and formic acid; dicarboxylic acid compounds such as malonic acid, succinic acid, adipic acid, maleic acid, and fumaric acid; hydroxycarboxylic acid compounds such as malic acid, lactic acid, glycolic acid, gluconic acid, and citric acid; amino acid compounds such as glycine, alanine, iminodiacetic acid, arginine, aspartic acid, and glutamic acid; and aminopolycarboxylic acid compounds such as iminodiacetic acid, nitrilotriacetic acid, ethylenediaminediacetic acid, ethylenediaminetetraacetic acid, and diethylenetriaminepentaacetic acid.

The electrolytic plating method is, for example, a method of forming an electrolytic plating layer (coating) by bringing an electrolytic plating liquid into contact with the surface of an electroless plating layer (coating) formed by an electroless plating treatment, and then energizing the surface in a state of being in contact with the electrolytic plating liquid to precipitate a metal such as copper contained in the electrolytic plating liquid on the surface of the electroless plating layer (coating) formed by an electroless plating treatment and installed on a cathode.

The electrolytic plating liquid preferably contains the third metal atom contained in the above-described metal layer Y, an acid such as sulfuric acid or a carboxylic acid, and a solvent.

Examples of the solvent include a solvent which can be included in the above-described composition.

### EXAMPLES

Hereinbelow, the present invention will be described in more detail with reference to Examples.

The material, the amount used, the proportion, the process contents, the process procedure, and the like shown in the following examples can be appropriately changed, within a range not departing from the gist of the present invention. Therefore, the scope of the present invention is not construed as being limited to Examples shown below.

### [Preparation of Ink]

### <Ink 1>

Silver neodecanoate was added to a 2000 mL three-neck flask. Next, a limonene solution containing 3% by mass of 2,2,6,6-tetramethyl-3,5-heptanedione and 1.5% by mass of 3-glycidoxypropyltrimethoxysilane was added thereto, and the mixture was stirred to obtain a solution containing a silver salt. This solution was filtered using a membrane filter made of polytetrafluoroethylene (PTFE) having a pore diameter of 0.45 μm, thereby obtaining ink 1.

The content of the silver neodecanoate was 45% by mass with respect to the total mass of the solution containing a silver salt, and the content of the limonene solution was 55% by mass with respect to the total mass of the solution containing a silver salt.

### <Inks 2 to 5>

Inks 2 to 5 were prepared by the same procedure as in the ink 1, except that the content of the 3-glycidoxypropyltrimethoxysilane in each ink was changed to the value shown in the table below.

### Example 1

### <Step 1>

A diluted solution in which a titanium coupling agent (PC200, manufactured by Matsumoto Fine Chemical Co., Ltd.) was diluted to 16% by mass was obtained using a solution containing ethyl acetate/butanol=1:1 (volume ratio). The diluted solution was applied to a slide glass (S9111, manufactured by Matsunami Glass Co., Ltd.) using a #4 bar coater and dried at 120 °C for 30 seconds to form a metal oxide layer on a substrate, thereby obtaining a substrate with a metal oxide layer. The thickness of the metal oxide layer was 200 nm.

### <Step 2>

An ink jet recording device (product name “Samba G3L”, manufactured by FUJIFILM DIMATIX) was filled with the ink 5. As image recording conditions, the resolution was set to 1200 dots per inch (dpi), and the droplet volume was set to 5 pL per dot. A 3 mm×50 mm, 40 m (Wet) image was printed on the substrate with a metal oxide layer produced in the step 1 at 23 °C. Thereafter, the substrate was sintered at 180 °C for 60 minutes using a hot plate to form a metal layer X on the metal oxide layer, thereby obtaining a laminate of Example 1.

### Examples 2 to 12 and Comparative Examples 1 to 3

Each laminate was obtained by the same procedure as in Example 1, except that the conditions were changed as shown in the following table.

### [Measurement of Number of Atoms Contained in Metal Layer X]

For each laminate, Ag 3d, C is, O is, Si 2s, Ti 2p, Zr 3d, and Al 2p were analyzed in a 300 μm square by X-ray photoelectron spectroscopy (XPS) device (manufactured by ULVAC-PHI, Inc.). Ar sputtering was used for the depth direction analysis.

[Adhesiveness after Plating Liquid Immersion]

A sample of a 5 cm square solid image was produced from each laminate. The obtained sample was immersed in the following plating liquid heated to 60 °C for 30 minutes. Thereafter, the sample was taken out from the plating liquid and dried at 60 °C for 30 minutes.

Plating liquid

| | | |
|---|---|---|
| NiSO₄•6H₂O | 0.95 | mol/L |
| NiCl₂•6H₂O | 0.17 | mol/L |
| H₃BO₃ | 0.49 | mol/L |
| FeSO₄•7H₂O | 0.35 | mol/L |
| C₇H₄NNaO₃S•2H₂O | 0.008 | mol/L |
| Malonic acid | 0.1 | mol/L |

A cross-hatch test was performed on the sample treated with the plating liquid by the following method, and the adhesiveness after plating liquid immersion was evaluated.

Six cuts were made in each of directions orthogonal to each other on the surface of the metal layer X. A tape piece of cellophane tape (“CELLOTAPE (registered trademark) CT-18”, manufactured by Nichiban Co., Ltd.) was attached to the metal layer X on which the cuts were formed, and then the tape piece was peeled off from the metal layer X. Peeling of the metal layer X on the surface from which the tape piece was peeled off (exposure of the underlayer) and the amount of the metal layer X attached to the peeled tape piece were visually observed, and the adhesiveness after plating liquid immersion was evaluated based on the following evaluation standard from the observation results.

<Evaluation Standard for Adhesiveness after Plating Liquid Immersion>

“5”: peeling was not observed on the surface of the metal layer X, and a black or silver adhered matter was not observed on the tape piece.

“4”: peeling of the metal layer X was slightly observed only at the intersection of the cuts on the surface of the metal layer X, and/or a black or silver adhered matter was slightly observed on the tape piece.

“3”: peeling of the metal layer X was slightly observed only at the intersection of the cuts on the surface of the metal layer X, and a black or silver adhered matter was observed on the tape piece, the adhered matter being attached to an area of less than 10% with respect to the area of the portion where the cuts were made by the cross-hatch.

“2”: peeling of the metal layer X was observed on the surface of the metal layer X in an area of less than 10% with respect to the area of the portion where the cuts were made by the cross-hatch, and/or a black or silver adhered matter was observed on the tape piece, the adhered matter being attached to an area of 10% or more and less than 50% with respect to the area of the portion where the cuts were made by the cross-hatch.

“1”: peeling of the metal layer X was observed on the surface of the metal layer X in an area of 10% or more with respect to the area of the portion where the cuts were made by the cross-hatch, and/or a black or silver adhered matter was observed on the tape piece, the adhered matter being attached to an area of 50% or more with respect to the area of the portion where the cuts were made by the cross-hatch.

### [Conductivity (Volume Resistivity)]

The resistance of each of the produced metal layers X was measured at room temperature (23 °C) using a resistance meter (product name “DT4222”, manufactured by HIOKI E.E. CORPORATION). In addition, the cross-sectional area of each of the laminates was measured at room temperature (23 °C) using a scanning electron microscope (product name “S-4700”, manufactured by Hitachi, Ltd.). A volume resistivity (μΩ·cm) was calculated from the measured resistance value and cross-sectional area, and the obtained volume resistivity was evaluated based on the following evaluation standard. As the volume resistivity is lower, the conductivity of the laminate is more excellent.

### <Evaluation Standard for Conductivity>

“5”: less than 10 μΩ·cm

“4”: 10 μΩ·cm or more and less than 15 μΩ·cm

“3”: 15 μΩ·cm or more and less than 17.5 μΩ·cm

“2”: 17.5 μΩ·cm or more and less than 20 μΩ·cm

“1”: 20 μΩ·cm or more

### [Migration Occurrence]

The metal layer X of each laminate was etched into a comb shape with a line and space (L/S) of 50/50 m by a photolithography method to form a comb-shaped silver wiring. In this case, Fotec H-7025 (product name, manufactured by Hitachi Chemical Co., Ltd.) was used as a dry film resist, and Agrip 940 (product name, manufactured by Meltex Inc.) was used as a silver etchant. Furthermore, Cytop (registered trademark) CTL-107MK (product name, manufactured by AGC Inc., amorphous fluororesin) was spin-coated on the obtained silver wiring such that the film thickness after drying was 1 μm. Thereafter, the resultant was dried in an oven at 140 °C for 20 minutes to form a sealing layer, thereby producing a wiring board for evaluation standard of migration occurrence.

The obtained wiring board was subjected to a life test (using device: EHS-221MD, manufactured by ESPEC Corp.) under the conditions of a relative humidity of 85%, a temperature of 85 °C, a pressure of 1.0 atm, and a voltage of 60 V. Specifically, in the above-described environment, the above-described voltage was continuously applied to the silver wiring (distance between silver wirings: 100 m) between adjacent teeth of the comb shape. Then, the short-circuit occurrence time from the start of the application to the short-circuiting between the silver wirings due to migration was measured.

### <Evaluation Standard for Migration Occurrence>

“3”: short-circuit occurrence time was 400 minutes or more.

“2”: short-circuit occurrence time was 300 minutes or more and less than 400 minutes.

“1”: short-circuit occurrence time was less than 300 minutes.

In the table,

“SR” represents an E-green solder paste (SR) plate (FR-4, 1.6 t) manufactured by Matsuwa Sangyo Co., Ltd.

Each metal oxide layer was formed according to the procedure of Example 1 using a titanium coupling agent (PC200, manufactured by Matsumoto Fine Chemical Co., Ltd.) in a case where the column of “First metal atom” was “Ti”, according to the procedure of Example 1 using a zirconium coupling agent (Zr-540, manufactured by Matsumoto Fine Chemical Co., Ltd.) instead of the titanium coupling agent in a case where the column of “First metal atom” was “Zr”, and according to the procedure of Example 1 using an aluminum coupling agent (ethyl acetoacetate aluminum diisopropylate, manufactured by FUJIFILM Wako Pure Chemical Corporation) instead of the titanium coupling agent in a case where the column of “First metal atom” was “Al”.

The “GSC amount” indicates the content of 3-glycidoxypropyltrimethoxysilane (silane coupling agent) with respect to the total mass of the ink.

“Si/(O+C)” indicates a ratio of the number of silicon atoms to the total number of oxygen atoms and carbon atoms (number of silicon atoms/total number of oxygen atoms and carbon atoms).

“Si content”, “O content”, and “C content” indicate the content of each atom with respect to the total number of atoms of the metal layer X.

TABLE 1

| | | | | Metal layer X | | | | | | | | Evaluation | | |
|---|---|---|---|---|---|---|---|---|---|---|---|---|---|---|
| | | | | Ink | | | | | | | | Adhesive- | | |
| | | Metal oxide layer | | | GSC | | | | | | | ness after | | |
| | | First | Thick- | | amount | Second | Thick- | Si/ | Si | O | C | plating | | |
| | Sub- | metal | ness | | (% by | metal | ness | (O + | content | content | content | liquid | conduc- | Migration |
| | strate | atom | (nm) | Type | mass) | atom | (μm) | C) | (at %) | (at %) | (at %) | immersion | tivity | occurrence |
| Example 1 | Glass | Ti | 200 | Ink 5 | — | Ag | 1.0 | 0 | 0 | 1.0 | 1.0 | 3 | 5 | 3 |
| Example 2 | Glass | Ti | 200 | Ink 1 | 1.5 | Ag | 1.0 | 0.44 | 4.0 | 4.5 | 4.5 | 5 | 5 | 3 |
| Example 3 | Glass | Ti | 60 | Ink 1 | 1.5 | Ag | 1.0 | 0.44 | 4.0 | 4.5 | 4.5 | 5 | 5 | 3 |
| Example 4 | Glass | Ti | 900 | Ink 1 | 1.5 | Ag | 1.0 | 0.44 | 4.0 | 4.5 | 4.5 | 5 | 5 | 3 |
| Example 5 | Glass | Ti | 200 | Ink 1 | 1.5 | Ag | 0.2 | 0.50 | 4.0 | 4.0 | 4.0 | 5 | 5 | 3 |
| Example 6 | Glass | Ti | 200 | Ink 1 | 1.5 | Ag | 3.5 | 0.38 | 4.0 | 5.0 | 5.5 | 4 | 5 | 3 |
| Example 7 | SR | Ti | 200 | Ink 1 | 1.5 | Ag | 1.0 | 0.44 | 4.0 | 4.5 | 4.5 | 5 | 5 | 3 |
| Example 8 | Glass | Ti | 200 | Ink 2 | 0.75 | Ag | 1.0 | 0.36 | 2.0 | 2.5 | 3.0 | 5 | 5 | 3 |
| Example 9 | Glass | Ti | 200 | Ink 3 | 3.0 | Ag | 1.0 | 0.27 | 7.0 | 12.0 | 14.0 | 5 | 5 | 3 |
| Example 10 | Glass | Ti | 200 | Ink 4 | 4.5 | Ag | 1.0 | 0.23 | 10.1 | 22.0 | 22.0 | 5 | 3 | 2 |
| Example 11 | Glass | Zr | 200 | Ink 1 | 1.5 | Ag | 1.0 | 0.44 | 4.0 | 4.5 | 4.5 | 4 | 5 | 3 |
| Example 12 | Glass | Al | 200 | Ink 1 | 1.5 | Ag | 1.0 | 0.44 | 4.0 | 4.5 | 4.5 | 4 | 5 | 3 |
| Comparative | Glass | — | — | Ink 1 | 1.5 | Ag | 1.0 | 0.47 | 4.0 | 4.0 | 4.5 | 1 | 5 | 3 |
| Example 1 | | | | | | | | | | | | | | |
| Comparative | Glass | Ti | 25 | Ink 1 | 1.5 | Ag | 1.0 | 0.47 | 4.0 | 4.0 | 4.5 | 2 | 5 | 3 |
| Example 2 | | | | | | | | | | | | | | |
| Comparative | Glass | Ti | 2500 | Ink 1 | 1.5 | Ag | 1.0 | 0.47 | 4.0 | 4.0 | 4.5 | 2 | 5 | 3 |
| Example 3 | | | | | | | | | | | | | | |

From the evaluation results shown in the table, it was confirmed that, in a case of the laminate according to the embodiment of the present invention and the laminate manufactured by the method for manufacturing a laminate according to the embodiment of the present invention, the adhesiveness after plating liquid immersion was excellent (Examples 1 to 12).

It was confirmed that, in a case where the metal layer X contained a silicon atom, the adhesiveness after plating liquid immersion was more excellent (comparison between Example 1 and Examples 2 to 12, and the like).

It was confirmed that, in a case where the number of silicon atoms in the metal layer X was 0.1 to 10.0 at % with respect to the total number of atoms of the metal layer X, the conductivity was more excellent, and the migration occurrence could be further suppressed (Examples 1 to 9 and 11 and 12). In addition, from the same comparison, it was confirmed that, in a case where the metal layer X contained an oxygen atom and a carbon atom, and the ratio of the number of silicon atoms to the total number of oxygen atoms and carbon atoms in the metal layer X was 0.25 or more, the conductivity was more excellent, and the migration occurrence could be further suppressed.

It was confirmed that, in a case where the first metal atom contained a titanium atom, the adhesiveness after plating liquid immersion was more excellent (comparison between Examples 2 to 9 and Examples 11 and 12, and the like).

It was confirmed that, in a case where the thickness of the metal layer X was 0.1 to 3.0 m, the adhesiveness after plating liquid immersion was more excellent (comparison between Examples 2 to 9, and the like).

What is claimed is:

1. A laminate comprising:
a substrate;
a metal oxide layer containing a first metal atom selected from the group consisting of a titanium atom, a zirconium atom, and an aluminum atom; and
a metal layer X disposed adjacent to the metal oxide layer and containing a second metal atom of a different kind from the first metal atom,
wherein a thickness of the metal oxide layer is 50 to 2,000 nm.

2. The laminate according to claim 1,
wherein the metal layer X contains a silicon atom.

3. The laminate according to claim 1,
wherein the metal layer X contains a silicon atom, and
the number of silicon atoms in the metal layer X is 0.1 to 10.0 at % with respect to a total number of atoms of the metal layer X.

4. The laminate according to claim 1,
wherein the metal layer X contains a silicon atom, an oxygen atom, and a carbon atom, and
a ratio of the number of silicon atoms to a total number of oxygen atoms and carbon atoms in the metal layer X is 0.25 or more.

5. The laminate according to claim 1,
wherein a thickness of the metal layer X is 0.1 to 3.0 μm.

6. The laminate according to claim 1, further comprising:
a metal layer Y, on the metal layer X, the metal layer Y containing a third metal atom of a different kind from both the first metal atom and the second metal atom.

7. A method for manufacturing a laminate, comprising:
a step 1 of applying a composition containing a coupling agent selected from the group consisting of a titanium coupling agent, a zirconium coupling agent, and an aluminum coupling agent onto a substrate to form a metal oxide layer containing a first metal atom selected from the group consisting of a titanium atom, a zirconium atom, and an aluminum atom; and
a step 2 of applying an ink containing a metal compound selected from the group consisting of a metal salt and a metal complex onto the metal oxide layer to form a metal layer X containing a second metal atom of a different kind from the first metal atom,
wherein a thickness of the metal oxide layer is 50 to 2,000 nm.

8. The method for manufacturing a laminate according to claim 7,
wherein the ink contains a silane coupling agent.

9. The method for manufacturing a laminate according to claim 7, further comprising:
a step 3 of subjecting the metal layer X to a plating treatment to form, on the metal layer X, a metal layer Y containing a third metal atom of a different kind from both the first metal atom and the second metal atom, after the step 2.

10. The laminate according to claim 2,
wherein the metal layer X contains a silicon atom, and
the number of silicon atoms in the metal layer X is 0.1 to 10.0 at % with respect to a total number of atoms of the metal layer X.

11. The laminate according to claim 2,
wherein the metal layer X contains a silicon atom, an oxygen atom, and a carbon atom, and
a ratio of the number of silicon atoms to a total number of oxygen atoms and carbon atoms in the metal layer X is 0.25 or more.

12. The laminate according to claim 2,
wherein a thickness of the metal layer X is 0.1 to 3.0 μm.

13. The laminate according to claim 2, further comprising:
a metal layer Y, on the metal layer X, the metal layer Y containing a third metal atom of a different kind from both the first metal atom and the second metal atom.

14. The method for manufacturing a laminate according to claim 8, further comprising:
a step 3 of subjecting the metal layer X to a plating treatment to form, on the metal layer X, a metal layer Y containing a third metal atom of a different kind from both the first metal atom and the second metal atom, after the step 2.

15. The laminate according to claim 3,
wherein the metal layer X contains a silicon atom, an oxygen atom, and a carbon atom, and
a ratio of the number of silicon atoms to a total number of oxygen atoms and carbon atoms in the metal layer X is 0.25 or more.

16. The laminate according to claim 3,
wherein a thickness of the metal layer X is 0.1 to 3.0 μm.

17. The laminate according to claim 3, further comprising:
a metal layer Y, on the metal layer X, the metal layer Y containing a third metal atom of a different kind from both the first metal atom and the second metal atom.

18. The laminate according to claim 4,
wherein a thickness of the metal layer X is 0.1 to 3.0 μm.

19. The laminate according to claim 4, further comprising:
a metal layer Y, on the metal layer X, the metal layer Y containing a third metal atom of a different kind from both the first metal atom and the second metal atom.

20. The laminate according to claim 5, further comprising:
a metal layer Y, on the metal layer X, the metal layer Y containing a third metal atom of a different kind from both the first metal atom and the second metal atom.
